(19) United States
(12) Patent Application Publication
(10) Pub. No.: US 2026/0337486 A1
(43) Pub. Date: Oct. 29, 2026

(54) PHOSPHOR, LIGHT-EMITTING DEVICE, LIGHTING DEVICE, IMAGE DISPLAY DEVICE, AND VEHICLE INDICATOR LAMP

(71) Applicants: Mitsubishi Chemical Corporation, Tokyo (JP); NATIONAL INSTITUTE FOR MATERIALS SCIENCE, Ibaraki (JP)

(72) Inventors: Hajime MATSUMOTO, Tokyo (JP); Kyota UEDA, Tokyo (JP); Naoto HIROSAKI, Ibaraki (JP); Kazutaka MITSUISHI, Ibaraki (JP)

(73) Assignees: Mitsubishi Chemical Corporation, Tokyo (JP); NATIONAL INSTITUTE FOR MATERIALS SCIENCE, Ibaraki (JP)

(21) Appl. No.: 19/697,658

(22) Filed: Jun. 4, 2026

Related U.S. Application Data
(63) Continuation of application No. PCT/JP2024/043123, filed on Dec. 5, 2024.

(30) Foreign Application Priority Data
Dec. 6, 2023 (JP) 2023-206225
Dec. 6, 2023 (JP) 2023-206226

(51) Int. Cl. C09K 11/77; H10H 20/851

(52) U.S. Cl. CPC C09K 11/77348; H10H 20/8511

(57) ABSTRACT

A phosphor includes a crystal phase having a composition represented by Formula [1] below, in which the phosphor includes stacking faults, and in a direction perpendicular to the stacking faults, a maximum value of a spacing between the stacking faults is 50 nm or greater, or pertains to a phosphor that includes a crystal phase A and a crystal phase B, in which both the crystal phase A and the crystal phase B have a composition represented by Formula [1] below, and the crystal phase A and the crystal phase B have mutually different space groups. ReₓMA₁₋ₓMB_{b}MC_{c}D_{d} [1]. The symbols in Formula [1] are as defined in the specification.

### CROSS-REFERENCE TO RELATED APPLICATIONS

This application is a continuation of International Application No. PCT/JP2024/043123, filed on Dec. 5, 2024, and claims the benefit of priority to Japanese Application No. 2023-206225 filed on Dec. 6, 2023 and Japanese Application No. 2023-206226 filed on Dec. 6, 2023. The content of each of these applications is hereby incorporated by reference in its entirety.

### TECHNICAL FIELD

The present invention relates to a phosphor, a light-emitting device, a lighting device, an image display device, and a vehicle indicator lamp.

### BACKGROUND ART

In recent years, the demand for lighting or backlighting using LEDs has increased in response to the trend for energy savings. The LEDs used in such lighting are white light-emitting LEDs in which a phosphor is disposed on an LED chip that emits light of blue or near-ultraviolet wavelengths.

As this type of white light-emitting LED, in recent years, a white light-emitting LED has been used in which a nitride phosphor that emits red light and a phosphor that emits green light using blue light from a blue LED chip as excitation light are mounted on the blue LED chip. In particular, as a nitride phosphor that emits red light, a phosphor in which an activator is added to a host represented by General Formula CaAlSi(N,O)₃ (hereinafter, which may be described as a “CASN phosphor”) or (Sr,Ca)AlSi(N,O)₃ (hereinafter, which may be described as a “SCASN phosphor”), and the like have been developed. From research into improvements and enhancements in reliability, and the actual results of specifications, CASN phosphors and SCASN phosphors are known to have excellent emission intensity, quantum efficiency, or the like.

### CITATION LIST

### Non-Patent Literature

Non-Patent Literature 1: Electrochemical and Solid-State Letters, vol. 9, H22 (2006)

### SUMMARY OF INVENTION

### Technical Problem

Incidentally, when the full width at half maximum (FWHM) of the peak of the emission spectrum of a phosphor is wide, the emission of light having a wavelength far from the target emission peak wavelength increases, and an emission color exhibiting the target chromaticity coordinates may not be obtained in some cases. In addition, in the case of a red phosphor, the emission of light of a wavelength range of low specific luminosity, such as 700 nm or greater, increases, and this increase is a factor that contributes to a decrease in the conversion efficiency of a light-emitting device. For this reason, a phosphor having a peak with a narrower full width at half maximum is required. In view of the above, an object of the present invention is to provide a phosphor having a narrow full width at half maximum of the peak and/or a light-emitting device excelling in emission color, conversion efficiency, or both.

### Solution to Problem

The present inventors discovered that the above problems can be solved by using a phosphor having specific crystal structural features, with the phosphor being of General Formula CASN or General Formula SCASN, and thereby arrived at the present invention.

Several non-limiting embodiments are presented below. However, it should be noted that the present invention also includes embodiments in which some or all of the features of one or more other embodiments are also included in any of the embodiments described below.

That is, the gist of the present invention is as follows.

Aspect 1 of the present invention pertains to:
a phosphor including a crystal phase having a composition represented by Formula [1] below,
the phosphor including stacking faults, and
in a direction perpendicular to the stacking faults, a maximum value of a spacing between the stacking faults being 50 nm or greater.

ReₓMA₁₋ₓMB_{b}MC_{c}D_{d} [1]
(In Formula [1],
Re includes one or more elements selected from the group consisting of Eu, Mn, Ce, Pr, Nd, Sm, Tb, Dy, Ho, Er, Tm, and Yb,
MA includes one or more elements selected from the group consisting of Ca, Sr, Ba, and Mg,
MB includes one or more elements selected from the group consisting of Al, B (boron), Ga, In, and Sc,
MC includes one or more elements selected from the group consisting of Si, Ge, Ti, and Hf,
D includes one or more elements selected from the group consisting of N (nitrogen), O (oxygen), F (fluorine), Cl, Br, and I (iodine), and also at least N (nitrogen), and
x, b, c, and d each independently satisfy the following.
   0.0<x≤0.2
   0.7≤b≤1.3
   0.7≤c≤1.3
   2.4≤d≤3.6)

Aspect 2 of the present invention pertains to the phosphor of aspect 1, wherein,
in the direction perpendicular to the stacking faults, the maximum value of the spacing between the stacking faults is 100 nm or greater.

Aspect 3 of the present invention pertains to the phosphor of aspect 1 or 2, wherein
a density of the stacking faults in a normal direction is 2×10⁵ cm⁻¹ or greater.

Aspect 4 of the present invention pertains to the phosphor according to any one of aspects 1 to 3, wherein
a space group of the crystal phase having a composition represented by Formula [1] is any one of Cmc2₁, Pbcn, P1, P-1, and a space group belonging to a maximal non-isomorphic subgroup derived from Cmc2₁ and Pbcn.

Aspect 5 of the present invention pertains to:
a phosphor including a crystal phase A and a crystal phase B,
both the crystal phase A and the crystal phase B having a composition represented by Formula [1] below, and
the crystal phase A and the crystal phase B having mutually different space groups.

ReₓMA₁₋ₓMB_{b}MC_{c}D_{d} [1]
(In Formula [1],
Re includes one or more elements selected from the group consisting of Eu, Mn, Ce, Pr, Nd, Sm, Tb, Dy, Ho, Er, Tm, and Yb,
MA includes one or more elements selected from the group consisting of Ca, Sr, Ba, and Mg,
MB includes one or more elements selected from the group consisting of Al, B (boron), Ga, In, and Sc,
MC includes one or more elements selected from the group consisting of Si, Ge, Ti, and Hf,
D includes one or more elements selected from the group consisting of N (nitrogen), O (oxygen), F (fluorine), Cl, Br, and I (iodine), and also at least N (nitrogen), and
x, b, c, and d each independently satisfy the following.
   0.0<x≤0.2
   0.7≤b≤1.3
   0.7≤c≤1.3
   2.4≤d≤3.6)

Aspect 6 of the present invention pertains to the phosphor of aspect 5, wherein
a volume occupancy rate of the crystal phase A is 60% or greater and less than 100% when a total of volume occupancy rates of the crystal phase A and the crystal phase B is 100%.

Aspect 7 of the present invention pertains to the phosphor of aspect 5 or 6, wherein
the space groups of the crystal phase A and the crystal phase B having the composition represented by Formula [1] are each any one of Cmc2₁, Pbcn, P1, P-1, and a space group belonging to a maximal non-isomorphic subgroup derived from Cmc2₁ and Pbcn.

Aspect 8 of the present invention pertains to:
a light-emitting device provided with a first light emitter and a second light emitter that emits visible light when irradiated with light from the first light emitter,
the second light emitter including the phosphor described in any one of aspects 1 to 7.

Aspect 9 of the present invention pertains to the light-emitting device of aspect 8, wherein
the second light emitter contains at least a red phosphor, further contains a green phosphor and/or a yellow phosphor, and includes, as the red phosphor or the yellow phosphor, the phosphor described in any one of aspects 1 to 7.

Aspect 10 of the present invention pertains to the light-emitting device of aspect 9, wherein
the green phosphor and/or the yellow phosphor includes one or more selected from the group consisting of a garnet-based phosphor, a silicate-based phosphor, a nitride phosphor, and an oxynitride phosphor.

Aspect 11 of the present invention pertains to:
a lighting device provided with, as a light source, the light-emitting device described in any one of aspects 8 to 10.

Aspect 12 of the present invention pertains to:
an image display device provided with, as a light source, the light-emitting device described in any one of aspects 8 to 10.

Aspect 13 of the present invention pertains to:
a vehicle indicator lamp provided with, as a light source, the light-emitting device described in any one of aspects 8 to 10.

### Advantageous Effects of Invention

According to the present invention, a phosphor having a peak with a narrow full width at half maximum, and/or a light-emitting device excelling in emission color, conversion efficiency, or both can be provided.

### BRIEF DESCRIPTION OF DRAWINGS

FIG. 1A is a schematic diagram of a sheet A having a sheet-like structure and is provided for explaining the crystal structure of CASN and a phosphor according to one embodiment of the present invention.

FIG. 1B is a schematic diagram of a sheet B having a sheet-like structure and is provided for explaining the crystal structure of CASN and a phosphor according to one embodiment of the present invention.

FIG. 1C is a schematic diagram of the crystal structure of a general CASN phosphor.

FIG. 1D is a schematic diagram of the crystal structure of a phosphor according to one embodiment of the present invention.

FIG. 2A is an image showing a selected area diffraction pattern in the [100] direction, the pattern being obtained by observing a phosphor of Example 1 with a transmission electron microscope.

FIG. 2B is an image in FIG. 2A, with explanatory notes added to indicate the positions of diffraction spots representing the (001) plane.

FIG. 2C is an image showing a selected area diffraction pattern in the [100] direction, the pattern being obtained by observing a phosphor of Comparative Example 1 with a transmission electron microscope.

FIG. 3A is a bright-field image obtained by observing the phosphor of Example 1 from the [100] direction with a transmission electron microscope.

FIG. 3B is a bright-field image obtained by observing the phosphor of Comparative Example 1 from the [100] direction with a transmission electron microscope.

FIG. 4A is an image showing a selected area diffractogram of the phosphor of Example 1 in a circular region with a diameter of 500 nm, obtained using a transmission electron microscope.

FIG. 4B is an image showing a centrally enlarged diffractogram obtained by observing the phosphor of Example 1 from the [100] direction through convergent beam electron diffraction (CBED).

FIG. 5A is an annular bright-field image obtained using an atomic resolution aberration-corrected scanning transmission electron microscope to observe, from the [100] direction, the phosphor of Example 1 in a region without stacking faults, or in a region consisting only of the crystal phase A of the phosphor of Example 1.

FIG. 5B is an image showing an enlarged view of FIG. 5A.

FIG. 6A is an image obtained by simulating a STEM bright-field image that should appear in calculations for a phosphor having the same composition as that of Example 1, when it is assumed that the space group is Cmc2₁.

FIG. 6B is an image obtained by simulating a STEM bright-field image that should appear in calculations for a phosphor having the same composition as that of Example 1, when it is assumed that the space group is Pbcn.

FIG. 7A is an integrated differential phase-contrast image obtained using an atomic resolution aberration-corrected scanning transmission electron microscope to observe, from the [100] direction, the phosphor of Example 1 in a region without stacking faults, or in a region consisting only of the crystal phase A of the phosphor of Example 1.

FIG. 7B is a diagram showing atomic modeling derived from FIG. 7A.

FIG. 8A is a graph showing normalized absorption spectra of the phosphors of Example 1 and Comparative Example 1.

FIG. 8B is a graph showing normalized emission spectra of the phosphors of Example 1 and Comparative Example 1.

### DESCRIPTION OF EMBODIMENTS

Hereinafter, the present invention will be described through embodiments and examples. However, the present invention is not limited to the following embodiments and examples and can be freely modified and carried out within a scope that does not depart from the gist of the present invention.

### Phosphor Composition

A phosphor according to an embodiment of the present invention is a phosphor that includes a crystal phase having a composition represented by Formula [1] below, wherein the phosphor includes stacking faults, and a maximum value of a spacing between the stacking faults in a direction perpendicular to the stacking faults is 50 nm or greater (hereinafter, such an embodiment is referred to as “embodiment A”).

Moreover, a phosphor according to an embodiment of the present invention is a phosphor that includes a crystal phase A and a crystal phase B, wherein both the crystal phase A and the crystal phase B have a composition represented by Formula [1] below, and the crystal phase A and the crystal phase B have mutually different space groups (hereinafter, such an embodiment is referred to as “embodiment B”).

Hereinafter, the phosphor corresponding to at least one of the embodiment A or the embodiment B may be referred to as a “phosphor according to the first embodiment”.

ReₓMA₁₋ₓMB_{b}MC_{c}D_{d} [1]
(In Formula [1],
Re includes one or more elements selected from the group consisting of Eu, Mn, Ce, Pr, Nd, Sm, Tb, Dy, Ho, Er, Tm, and Yb,
MA includes one or more elements selected from the group consisting of Ca, Sr, Ba, and Mg,
MB includes one or more elements selected from the group consisting of Al, B (boron), Ga, In, and Sc,
MC includes one or more elements selected from the group consisting of Si, Ge, Ti, and Hf,
D includes one or more elements selected from the group consisting of N (nitrogen), O (oxygen), F (fluorine), Cl, Br, and I (iodine), and also at least N (nitrogen), and
x, b, c, and d each independently satisfy the following.
   0.0<x≤0.2
   0.7≤b≤1.3
   0.7≤c≤1.3
   2.4≤d 3.6)

In Formula [1], Re includes one or more elements selected from the group consisting of europium (Eu), manganese (Mn), cerium (Ce), praseodymium (Pr), neodymium (Nd), samarium (Sm), terbium (Tb), dysprosium (Dy), holmium (Ho), erbium (Er), thulium (Tm), and ytterbium (Yb), and preferably includes at least Eu or Ce, and Re more preferably includes one or more selected from the group consisting of Eu and Ce.

In an embodiment in which Re includes Eu, the proportion of europium (Eu) to all Re-activating elements is preferably 50 mol % or greater, more preferably 70 mol % or greater, and particularly preferably 90 mol % or greater.

When the phosphor contains an appropriate amount of the Re elements, a phosphor exhibiting a good emission intensity can be obtained.

In Formula [1], MA includes one or more elements selected from the group consisting of calcium (Ca), strontium (Sr), barium (Ba), and magnesium (Mg). Preferably, MA includes one or more selected from the group consisting of Ca and Sr.

In one embodiment, the elements included in the MA described above account for 70 mol % or more, preferably 80 mol % or more, more preferably 90 mol % or more, and even more preferably 95 mol % or more of the entire MA, and in a specific embodiment, the MA consists of the elements described above.

In Formula [1], MB includes one or more elements selected from the group consisting of aluminum (Al), boron (B), gallium (Ga), indium (In), and scandium (Sc), preferably includes one or more elements selected from the group consisting of Al, B, and Ga, and more preferably includes at least Al.

In one embodiment, the elements included in the MB described above account for 70 mol % or more, preferably 80 mol % or more, more preferably 90 mol % or more, and even more preferably 95 mol % or more of the entire MB, and in a specific embodiment, the MB consists of the elements described above.

In Formula [1], MC includes one or more elements selected from the group consisting of silicon (Si), germanium (Ge), titanium (Ti), and hafnium (Hf), and preferably contains at least Si.

In one embodiment, the elements included in the MC described above account for 70 mol % or more, preferably 80 mol % or more, more preferably 90 mol % or more, and even more preferably 95 mol % or more of the entire MC, and in a specific embodiment, the MC consists of the elements described above.

In Formula [1], D includes one or more elements selected from the group consisting of nitrogen (N), oxygen (O), fluorine (F), chlorine (Cl), bromine (Br), and iodine (I), preferably includes at least N (nitrogen) or O (oxygen), and more preferably includes at least N (nitrogen).

In the embodiment in which D includes nitrogen (N) or oxygen (O), the total proportion of nitrogen (N) and oxygen (O) in the entire D is usually 70 mol % or more, preferably 80 mol % or more, more preferably 90 mol % or more, and even more preferably 95 mol % or more of the entire D.

The nitrogen (N) or oxygen (O) may partially contain another element such as fluorine (F), chlorine (Cl), bromine (Br), or iodine (I). In the present invention, “containing an element” means both a form in which an element is substituted and a form in which an element is contained without being substituted.

In addition to the intended elements, impurity elements having similar properties may be unintentionally or inevitably mixed into the MA, MB, MC, D, and Re, but the present invention does not exclude these impurity elements as long as the essence or effect of the present invention is not impaired or the effect of the present invention is not lost.

Here, the impurity element may be an element that was not intended to be included at each site among the elements listed as the elements that can be included in the MA, MB, MC, D, and Re, or may be an element other than the elements listed above.

For example, when a phosphor is produced with the intention of a composition in which the MA is composed of Ca and/or Sr, the MA may be partially substituted with another element such as Ba or Mg due to inevitable contamination of elements other than Ca and Sr described above in the raw materials, or due to contamination in a trace amount when a flux (fusing agent) is used in the production of the phosphor. However, the present invention does not exclude these cases as long as the essence of the present invention is not impaired or the effect of the present invention is not lost. The same applies to cases in which the “MA” in the description is replaced with MB, MC, D, or Re, the “Ca or Sr” in the description above is replaced with one or more of the elements listed as elements that can be included at each site, and “another element such as Ba or Mg” in the description above is replaced with “other elements”.

Oxygen (O) may be intentionally included for the purpose of maintaining the charge balance of the entire phosphor or for the purpose of adjusting the peak wavelength, but even when the phosphor is produced with the intention of not containing oxygen, oxygen may be mixed in as an impurity in the raw material metals, or may be mixed in during the production process such as in a pulverization step or the nitriding step. Thus, in the phosphor according to an embodiment of the present invention, oxygen may be inevitably mixed in even when not intended.

The allowable content of oxygen when production is carried out with Formula [1] not containing oxygen is usually 10 mass % or less, preferably 6 mass % or less, more preferably 4 mass % or less, and even more preferably 2 mass % or less, within a range in which a decrease in the luminescence characteristics of the phosphor can be tolerated.

Similar to oxygen, a halogen element may be contained in the phosphor according to the first embodiment. Conceivable factors causing a halogen element to be contained in the phosphor include a halogen element being mixed in as an impurity in the raw material metal or being introduced during a production process such as during a pulverization step or nitriding step. In particular, when a halide is used as the flux, a halogen element may be contained in the phosphor.

As described above, examples of halogen elements that may be mixed in include fluorine, chlorine, bromine, and iodine elements. From the viewpoint of the luminescence characteristics of the phosphor being acceptable, the content of the halogen element is preferably 1 mass % or less and more preferably 0.5 mass % or less.

In Formula [1], x, b, c, and d represent the equivalent amounts of Re, MB, MC, and D, respectively, when the total amount of MA+Re is 1 on a molar basis. The ideal ratio at which the crystal structure is stable is a case in which b, c, and d are 1, 1, and 3, respectively, but in practice, the values of b, c, and d may vary to some extent from the ideal ratio due to various causes such as single atom deficiency, a change in composition due to oxidation of the phosphor surface, a heterophase, and charge compensation. However, the present invention does not exclude these cases as long as the essence of the present invention is not impaired or the effect of the present invention is not lost. Specifically, the allowable ranges of the numerical values of x, b, c, and d are as described below.

The value of x is greater than 0.0 and 0.20 or less. Moreover, the value of x is preferably 0.00001 or greater, more preferably 0.001 or greater, and even more preferably 0.005 or greater, and is preferably 0.15 or less, more preferably 0.10 or less, even more preferably 0.05 or less, and particularly preferably 0.01 or less. When the value of x is in the above range, a good emission intensity can be obtained.

The range of b is 0.7 or greater and 1.3 or less. The range of b is preferably 0.8 or greater, more preferably 0.9 or greater, and even more preferably 0.95 or greater, and is preferably 1.2 or less, more preferably 1.1 or less, and even more preferably 1.05 or less.

The range of c is 0.7 or greater and 1.3 or less. The range of c is preferably 0.8 or greater, more preferably 0.9 or greater, and even more preferably 0.95 or greater, and is preferably 1.2 or less, more preferably 1.1 or less, and even more preferably 1.05 or less.

The range of d is 2.4 or greater and 3.6 or less. The range of d is preferably 2.6 or greater, more preferably 2.7 or greater, and even more preferably 2.8 or greater, and is preferably 3.4 or less, more preferably 3.3 or less, and even more preferably 3.2 or less.

When b, c, and d are within the above ranges, the crystal structure of the phosphor is stabilized.

### Crystal Structure

### Crystal Structure of Phosphor in Embodiment A

With regard to embodiment A, the phosphor according to the first embodiment is a phosphor that includes a crystal phase having a composition represented by Formula [1] and also includes stacking faults.

In general, a perfect crystal can be considered to be a state or structure in which the atomic planes constituting the crystal are repeatedly stacked with a certain regularity. Furthermore, a planar defect caused by disorder of the stacking regularity is referred to as a stacking fault. Examples of specific forms of stacking faults include a lack of a necessary layer, an insertion of an extra layer, and the occurrence of stacking in an order different from the original regularity.

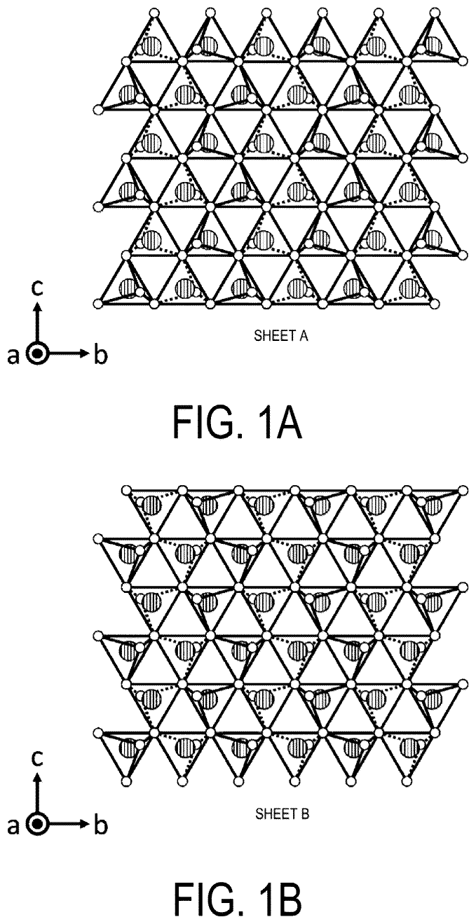

Next, the crystal structure of a known CASN phosphor will be described. As shown in FIG. 1C, the crystal structure of the CASN phosphor has a sheet-like structure (hereinafter, which may be referred to as “sheet A”, see FIG. 1A) in which AlN₄ or SiN₄ tetrahedra are spread out with shared vertices on the be plane of the crystal lattice or on a plane parallel to the lattice plane represented by the Miller indices (100), and the sheets A are stacked in the a-axis direction (reference document: Electrochemical and Solid-State Letters, vol. 9, H22 (2006), etc.).

It should be noted that in FIGS. 1A to 1D, the horizontally striped circles represent the MA sites (Ca and Sr sites in the CASN and SCASN phosphors) in Formula [1], the vertically striped circles represent the MB and MC sites (Si and Al sites in the CASN and SCASN phosphors), the white circles represent the D sites (N sites in the CASN and SCASN phosphors), the solid lines represent lines connecting the D sites, and the dashed lines represent lines connecting the D sites on the back side of the paper surface to other D sites.

As illustrated in FIG. 1D, the phosphor according to one embodiment of the present invention has a stacked structure similar to that of the CASN phosphor as a main phase, and includes stacking faults in the form in which a layer structure (hereinafter, which may be referred to as a “sheet B”, see FIG. 1B) with the sheet A rotated 180° about the a-axis is inserted partially or locally.

In the phosphor according to an embodiment of the present invention, the maximum value of the spacing between the stacking faults is 50 nm or greater in a direction perpendicular to the stacking faults.

The maximum value of the spacing between the stacking faults is, in order from the most preferred embodiment, 2.0 μm or greater, 1.5 μm or greater, 1.2 μm or greater, 1.0 μm or greater, 800 nm or greater, 500 nm or greater, 300 nm or greater, 200 nm or greater, 100 nm or greater, 80 nm or greater, and the abovementioned 50 nm or greater.

When the maximum value of the spacing between the stacking faults is within the above range, a phosphor having a peak with a narrower full width at half maximum can be obtained.

This principle is considered to be based on the following reasons, for example. The formation of stacking faults, that is, the expansion of dislocations, causes complete dislocations to be decomposed into Shockley partial dislocations, thereby significantly relieving the residual stress of the phosphor and localizing stacking faults and the Shockley partial dislocations in the vicinity thereof. This ensures a wide region that can be said to be an almost perfect crystal in which neither dislocations nor stacking faults are present. In the almost perfect crystal region, the crystal field is stable, and thereby the radiation path is narrowed, making it easier to obtain a phosphor having a narrow full width at half maximum. In addition, in the region with small strain, the Re element serving as the emission center easily hops, and the distribution of Re becomes relatively uniform, that is, the distance between the Re elements becomes nearly equidistant, and the crystal field around each Re element is also made uniform. Consequently, the wavelengths at which the intensity of light emission attributable to each Re is maximized also become close, and as a result, there is a potential for the full width at half maximum of the entire phosphor to become narrow.

Moreover, in one embodiment, the maximum value of the spacing between the stacking faults is 5.0 μm or less, and in this embodiment, the maximum value of the spacing is preferably 4.0 μm or less, and more preferably 3.0 μm or less. In the present embodiment, when the spacing between the stacking faults is within the above range, dislocation splitting and a reduction in residual stress due to the formation of stacking faults (dislocation expansion) occur appropriately throughout the phosphor, and a phosphor having fewer dislocations or ideally no dislocations can be obtained. Note that the spacing is also referred to as a total area of stacking faults in a unit volume or a stacking fault probability, and is the same as a case in which the spacing is expressed as a stacking fault density in units of 1/cm.

In the present specification, a value measured by the following method is used as the spacing between the stacking faults.

That is, the stacking faults can be observed as lines on the phosphor surface by observing the phosphor surface from a direction parallel to the stacking faults using a transmission electron microscope (TEM) or a scanning transmission electron microscope (STEM). In a case in which a plurality of the stacking faults are present on the surface of the phosphor, the distance between the stacking faults that are closest to each other in a direction perpendicular to the stacking faults is measured.

In addition, in a case in which only one stacking fault is observed on the observation surface, when the maximum distance from the observed stacking fault to the end of the observation surface positioned in the direction perpendicular to the stacking fault is denoted as R, the maximum value of the spacing between the stacking faults can be considered to be at least equal to or greater than R.

In a specific embodiment, stacking faults are present on the be plane or in the direction of the Miller indices (100), and the spacing of the stacking faults is evaluated by the distance along the a-axis or in the [100] direction.

Moreover, in one embodiment, the density in the normal direction of the stacking faults is 2×10⁵ cm⁻¹ or greater, preferably 1×10⁵ cm⁻¹ or greater, and more preferably 5×10⁴ cm⁻¹ or greater. The upper limit of the density of the stacking faults in the normal direction is not particularly limited, and may be, for example, 2×10³ cm⁻¹ or less, 1×10³ cm⁻¹ or less, or 1×10² cm⁻¹ or less.

When the density of the stacking faults in the normal direction is 2×10⁵ cm⁻¹ or greater, the crystal field is stable, and thereby the path of radiation is narrowed, and a phosphor having a narrow full width at half maximum is easily obtained, which is preferable.

In the present specification, the density of the stacking faults in the normal direction is a value measured by the following method.

The density is equal to the total area of stacking faults in a unit volume, and it is also referred to as stacking fault probability. Such a density can be quantitatively determined by using a transmission electron microscope. An example of a method for measuring the total area (the stacking fault probability) is presented.

When an electron beam is incident in parallel to the stacking fault plane, a diffraction intensity derived from the stacking faults is generated in the electron beam diffractogram. The objective aperture is adjusted so as to include the diffraction intensity, and thereby linear stacking fault contrasts can be confirmed in an electron microscope image projected and recorded on a CCD camera or film. The spacing in the normal direction of the linear stacking fault contrast is determined and expressed in 1/cm. For example, when the spacing in the normal direction of the linear stacking fault contrast is 5 μm, the density of the stacking faults in the normal direction is 2×10³ cm⁻¹, and when the spacing is 500 nm, the density is 2×10⁴ cm⁻¹.

A phosphor according to an embodiment of the present invention includes a region not containing the stacking faults.

Moreover, in a specific embodiment, the phosphor includes at least one region that does not include the stacking faults and has a width of 50 nm or greater in a direction perpendicular to the stacking faults.

Further, the width of the region in the direction perpendicular to the stacking faults is, in order from the most preferred embodiment, 2.0 μm or greater, 1.5 μm or greater, 1.2 μm or greater, 1.0 μm or greater, 800 nm or greater, 500 nm or greater, 300 nm or greater, 200 nm or greater, 100 nm or greater, 80 nm or greater, or the abovementioned 50 nm or greater in the direction perpendicular to the stacking faults.

When the phosphor has a region containing no stacking faults, a phosphor having a region close to a perfect crystal and having a good emission peak intensity or a good full width at half maximum of the peak can be obtained.

A phosphor according to a specific embodiment of the present invention includes a region that does not include any stacking faults or dislocations. The width of the region in the direction perpendicular to the stacking faults may be the same as that of the above-described region that does not contain any stacking faults. By configuring a phosphor to have a region that is free of stacking faults and of dislocations, a phosphor having a region closer to a perfect crystal and having a good emission peak intensity or a good full width at half maximum of the peak can be obtained.

In one embodiment, a space group of the crystal phase having a composition represented by Formula [1] is any of Cmc2₁, Pbcn, P1, P-1, and a space group belonging to a maximal non-isomorphic subgroup derived from Cmc2₁ and Pbcn.

In a preferred embodiment, the space group of the crystal phase having the composition represented by Formula [1] is Cmc2₁.

### Phosphor Crystal Structure in Embodiment B

With regard to embodiment B, the phosphor according to the first embodiment includes a crystal phase A and a crystal phase B, both the crystal phase A and the crystal phase B have a composition represented by Formula [1], and the crystal phase A and the crystal phase B have mutually different space groups.

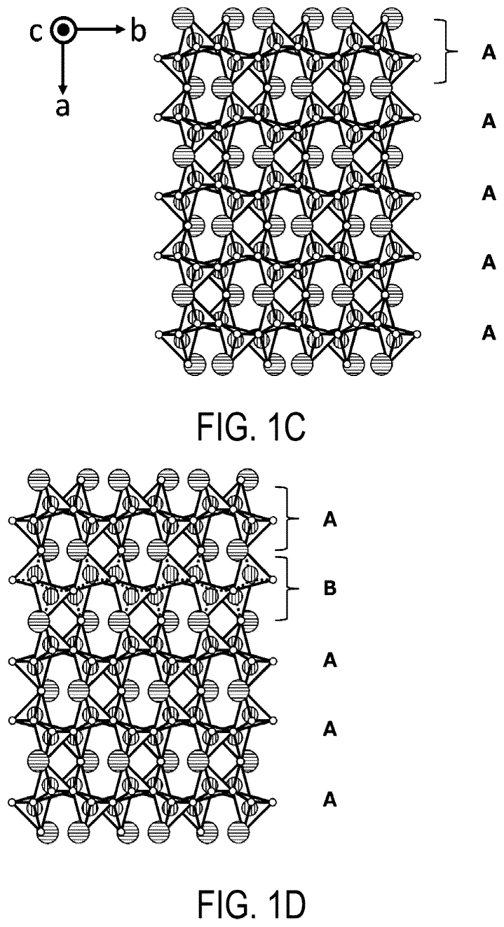

The crystal structure of the CASN phosphor is generally a sheet-like structure (hereinafter, which may be referred to as a “sheet A”, see FIG. 1A) in which AlN₄ or SiN₄ tetrahedra are spread out with shared vertices on a plane parallel to the lattice plane represented by the Miller indices (100) or on the be plane of the crystal lattice shown in FIG. 2 of the reference document (Electrochemical and Solid-State Letters, vol. 9, H22 (2006)), and can be expressed as a structure in which the sheets A are stacked in the a-axis direction (see FIG. 1C).

Meanwhile, in the phosphor according to the first embodiment, the crystal phase A exhibits a stacked structure similar to that of CASN, and the crystal phase B has a structure (see FIG. 1D) in which the minimum unit is a stacked structure of “sheet A→sheet B” in which a structure (hereinafter, which may be referred to as “sheet B”, see FIG. 1B) with the sheet A rotated 1800 about the a-axis is stacked. The insertion of the sheet B corresponds to a stacking fault in the form in which a phase that should not be stacked is inserted. It is considered that the sheet B is inserted by expansion of dislocations or the like, and a phosphor containing the crystal phase B is obtained.

In addition, each of the crystal phases B may independently consist of only one of the minimum units, or may have a structure in which the minimum unit is repeated a plurality of times. The number of repetitions is usually 1 or more and 10 or less, and is preferably 8 or less, more preferably 6 or less, even preferably 4 or less, and particularly preferably 3 or less.

In one embodiment, when the total of the volume occupancy rates of the crystal phase A and the crystal phase B is 100%, the volume occupancy rate of the crystal phase A is 60% or greater but less than 100%. The volume occupancy rate of the crystal phase A is preferably 65% or greater, more preferably 70% or greater, even more preferably 75% or greater, still more preferably 80% or greater, particularly preferably 82% or greater, and most preferably 85% or greater, and in a specific embodiment, the volume occupancy rate of the crystal phase A is preferably 99% or less, more preferably 97% or less, and even more preferably 95% or less.

When the volume occupancy rate of the crystal phase A is the above lower limit or greater, a region close to a perfect crystal can be sufficiently secured, and when the volume occupancy rate of the crystal phase A is the above upper limit or less, residual stress can be appropriately reduced in the entire region of the phosphor.

In one embodiment, in a direction perpendicular to the crystal phases B, the maximum value of the spacing between the crystal phases B is 50 nm or greater, and is preferably, in order from the most preferred embodiment, 2.0 μm or greater, 1.5 μm or greater, 1.2 μm or greater, 1.0 μm or greater, 800 nm or greater, 500 nm or greater, 300 nm or greater, 200 nm or greater, 100 nm or greater, 80 nm or greater, or the above 50 nm or greater. When this spacing is equal to or greater than the above lower limit, a region close to a perfect crystal can be sufficiently secured, and when the spacing is equal to or less than the upper limit, residual stress can be appropriately reduced in the entire region of the phosphor.

When the volume occupancy rate of the crystal phase B is within the above range, a phosphor having a peak with a narrower full width at half maximum can be obtained.

This principle is considered to be due to, for example, the following reasons. As an observation fact, a phosphor containing the crystal phase B tends to exhibit reduced dislocation as compared with a phosphor not containing the crystal phase B. Hence, it is considered that the residual stress of the entire phosphor is reduced by the phosphor appropriately containing the crystal phase B.

In addition, since the crystal phases B are present with a sufficient spacing therebetween, a region where no dislocation is present and which can be said to be an almost perfect crystal is widely secured. In the almost perfect crystal region, the crystal field is stable, and thereby the radiation path is narrowed, making it easier to obtain a phosphor having a narrow full width at half maximum. In addition, in the region with small strain, the Re element serving as the emission center easily hops, and the distribution of Re becomes relatively uniform, that is, the distance between the Re elements becomes nearly equidistant, and the crystal field around each Re element is also made uniform. Consequently, the wavelengths at which the intensity of light emission attributable to each Re is maximized also become close, and as a result, the full width at half maximum of the entire phosphor may become narrow.

In one embodiment, both the space groups of the crystal phases A and B having the composition represented by Formula [1] are any of Cmc2₁, Pbcn, P1, P-1, and a space group belonging to a maximal non-isomorphic subgroup derived from Cmc2₁ and Pbcn.

In a specific embodiment, the space group of the crystal phase A is Cmc2₁.

Moreover, in another specific embodiment, the space group of the crystal phase B is Pbcn, P1 or P-1, and is preferably Pbcn.

In yet another specific embodiment, the crystal phase B is missing nitrogen from the nitrogen site of the space group Cmc2₁. This corresponds to a case in which the crystal phase B belongs to a space group different from Cmc2₁, and can be confirmed, for example, from an image obtained using a below-described atomic resolution aberration-corrected scanning transmission electron microscope.

### Method for Determining Phosphor Space Groups

A method for determining the space groups of a phosphor according to the present invention will be described.

In general, in X-ray diffraction, the presence or absence of a central subject cannot be determined because of the establishment of kinematic approximation, and as a result, a space group cannot be determined, or a space group different from an actual space group may be erroneously determined.

### Method for Determining Space Group of Phosphor in Embodiment A

However, regarding the embodiment A, the presence or absence and distribution of regions that produce a specific diffraction peak can be identified using, for example, a dark-field TEM image, and the space groups can be more accurately identified by identifying the atomic arrangement using, for example, STEM.

For example, a space group can be confirmed by a method of analyzing a convergent beam electron diffraction (CBED) pattern, and the presence of a Cmc2₁ space group is revealed by the presence of two mirror symmetries (m) and a two-fold helical axis parallel to the c-axis direction. When only one mirror symmetry exists, the space group is P2₁, and when a two-fold helical axis parallel to the c-axis direction does not exist, the space group is Pbcn.

### Method for Determining Space Group of Phosphor in Embodiment B

Regarding the embodiment B, furthermore, in an X-ray diffraction pattern, the phosphor according to one embodiment of the present invention exhibits, in addition to the peak indicating the main phase, a small peak that suggests a different phase. In the phosphor according to the first embodiment, peaks corresponding to the crystal phase A and the crystal phase B appear.

As a result, when an attempt is made to determine the space groups of a phosphor according to the present embodiment only from observation by XRD, there is a possibility that a conclusion may be made that a space group differs from the originally intended space group.

For example, for a diffraction peak that would not normally appear, the presence or absence and distribution of a region in which the diffraction peak is generated can be identified from a dark-field TEM image in the relevant diffraction direction. In addition, a space group can be more accurately identified by identifying all atomic arrangements that include a nitrogen atom by using, for example, an image from an atomic resolution aberration-corrected scanning transmission electron microscope (STEM). Examples of STEM methods that can accurately identify the atomic arrangement of so-called light elements such as nitrogen include low-angle annular dark-field (LAADF-STEM), annular bright-field (ABF-STEM), and integrated differential phase contrast (iDPC-STEM), and the Cmc2₁ space group can be determined by using any of these methods.

### Range of “Identical Crystal Structure” Derived by Transmission Electron Microscopy

The lattice constant changes when the constituent elements Sr, Ca, Si, Al, and N are replaced with another element, and a metal element such as Eu forms a solid solution, and it is known that when this occurs, the following (1) and (2) apply.
(1) The crystal structure, the sites occupied by atoms, and the atomic position given by the coordinates thereof do not change.
(2) The crystal structure, the sites occupied by atoms, and the atomic positions given by the coordinates thereof do not change so much that the chemical bonds between the skeletal atoms are broken.

Furthermore, it is widely known as the Hume-Rothery rule that the crystal structure is not changed by a substitution with a difference in atomic radius up to 15%.

For example, when Ca (covalent radius: 180 pm) is replaced with Sr (covalent radius: 200 pm), the difference in atomic radius is

100×(200−180)/180=11.11%,
and thus the crystal structure remains the same.

Furthermore, when N (covalent radius: 65 pm) is replaced with O (covalent radius: 60 pm), the difference in atomic radius is

100(60−65)/65=7.69%,
and thus the crystal structure remains the same.

### Physical Properties of Phosphor

### Emission Color

Regarding embodiments A and B, by adjusting the chemical composition and the like, a phosphor according to one embodiment of the present invention can be achieved that is excited by light of wavelengths from 360 nm to 550 nm and exhibits a desired emission color such as blue, blue-green, green, yellow-green, yellow, orange, or red.

### Emission Spectrum

The wavelength of the emission peak and the shape thereof vary depending on the chemical composition of the phosphor or the type of Re element.

When Re includes Eu or is mainly composed of Eu, the emission peak wavelength λp (nm) in the emission spectrum of the phosphor is usually 570 nm or greater and 700 nm or less.

In the present specification, “Re is mainly composed of Eu” means that Eu accounts for 50 mol % or more, preferably 60 mol % or more, more preferably 70 mol % or more, and even more preferably 80 mol % or more of the entire Re. When the same expression is used for other elements included in MA, MB, MC, and D, the expression means that the other elements account for, of the entire Re, the mol % of the above-described range.

When MA is mainly composed of Ca, the emission peak wavelength is preferably 620 nm or greater, and more preferably 630 nm or greater, and is preferably 680 nm or less, and more preferably 660 nm or less. When MA contains Sr, the emission peak wavelength is preferably 580 nm or greater, and is preferably 640 nm or less, and more preferably 630 nm or less, and may be 620 nm or less, or 615 nm or less. When the emission peak wavelength λp (nm) is within the above range, the luminescence characteristics as orange or red light are favorable, which is preferable.

Moreover, the peak full width at half maximum (hereinafter, which may be appropriately abbreviated as “FWHM”) in the above-described emission spectrum of the phosphor is usually 50 nm or greater and 100 nm or less, preferably 90 nm or less, more preferably 80 nm or less, and even more preferably 75 nm or less. When the FWHM is within the above range and the phosphor is applied to a light-emitting device, both the color rendering property and the conversion efficiency of the light-emitting device are good, which is preferable.

When Re contains Ce or is mainly composed of Ce, the emission peak wavelength λp (nm) in the emission spectrum of the phosphor is usually 545 nm or greater, preferably 550 nm or greater, and more preferably 555 nm or greater, and is usually 580 nm or less, preferably 575 nm or less, and more preferably 570 nm or less.

Moreover, the peak full width at half maximum (hereinafter, which may be appropriately abbreviated as “FWHM”) in the above-described emission spectrum of the phosphor is usually 110 nm or greater and 145 nm or less, preferably 140 nm or less, more preferably 135 nm or less, and even more preferably 130 nm or less. When the FWHM is within the above range and the phosphor is applied to a light-emitting device, both the color rendering property and the conversion efficiency of the light-emitting device are good, which is preferable.

When Re contains both Eu and Ce or is mainly composed of Eu and Ce, the emission peak wavelength λp (nm) in the emission spectrum of the phosphor is usually 545 nm or greater, preferably 550 nm or greater, and more preferably 555 nm or greater, and is usually 680 nm or less, preferably 670 nm or less, and more preferably 660 nm or less.

Moreover, the peak full width at half maximum (hereinafter, which may be appropriately abbreviated as “FWHM”) in the above-described emission spectrum of the phosphor is usually 110 nm or greater and 165 nm or less, preferably 160 nm or less, more preferably 155 nm or less, and even more preferably 150 nm or less. When the FWHM is within the above range and the phosphor is applied to a light-emitting device, both the color rendering property and the conversion efficiency of the light-emitting device are good, which is preferable.

As a light source for exciting the phosphor, for example, a GaN-based light-emitting diode that emits light in the range of 445 to 460 nm can be used. The method for measuring the emission spectrum of the phosphor according to the first embodiment is not limited, and for example, the emission spectrum can be measured using a 150 W xenon lamp as an excitation light source and a spectrofluorometer provided with a multi-channel CCD detector as a spectrum measurement device. The emission peak wavelength and the peak full width at half maximum can be calculated from the obtained emission spectrum.

### Internal Quantum Efficiency

A higher internal quantum efficiency of the phosphor according to the first embodiment is more preferable. The value of the internal quantum efficiency is usually 0.86 or greater, and is preferably 0.88 or greater, more preferably 0.9 or greater, and particularly preferably 0.913 or greater. An internal quantum efficiency that is within the above range is preferable in that the emission efficiency is high.

### Phosphor Production Method

Regarding embodiments A and B, the method for producing the phosphor according to the first embodiment is not particularly limited as long as the phosphor according to the present invention is obtained, and examples of the production method include a production method that uses an alloy as a phosphor raw material (hereinafter, this method may be referred to as the “alloy method”) and a production method that uses a nitride of each element as a phosphor raw material (hereinafter, this method may be referred to as the “nitride method”). Hereinafter, an example of a method that can be used to obtain the phosphor according to the present invention will be described.

### Alloy Method

In a case in which the phosphor according to the first embodiment is produced by the alloy method, for example, when a phosphor having a composition represented by Formula [1] is to be produced, metals or alloys serving as raw materials (hereinafter, which may be simply referred to as “raw material metals”) are weighed such that a composition represented by Formula [2] below is obtained. Next, the raw materials are melted and alloyed to produce a phosphor raw material alloy, after which the phosphor raw material alloy is pulverized to produce an alloy powder, and the alloy powder is heated in a nitrogen-containing atmosphere and subjected to a nitriding treatment.

The process will be described in more detail below, but when melting the raw material metals as described later, it is preferable to melt Si metal, which has a high melting point (high boiling point) and/or an alloy containing Si, and then melt Ca and Sr, which have low melting points (low boiling points).

ReₓMA₁₋ₓMB_{b}MC_{c} [2]
(In Formula [2] above, Re, MA, MB, MC, x, b, and c have the same definition as in Formula [1].)

### Shape of Raw Material Metals

The shape of the raw material metals is not limited, but usually, a raw material metal having a granular or clumped shape with a diameter ranging from several mm to several tens of mm is used. When the phosphor according to the first embodiment contains Sr, a clump-shaped raw material is preferably used because Sr is chemically active in such form.

### Melting of Raw Material Metals

The raw material metals are weighed so as to obtain the target composition and then melted. The method for melting the raw material metals is not particularly limited, and a known method may be used. In addition, the raw material metals are preferably melted by melting the high melting point (high boiling point) Si metal and/or alloy containing Si and then melting the alkaline earth metal (Sr or Ca) having a low melting point (low boiling point). The method for melting the raw material metals in the present invention is not particularly limited, but typical examples include a resistance heating method, an electron beam method, an arc melting method, and a high-frequency induction heating method.

### Casting of Molten Metal

Although a nitrogen-containing alloy can be directly produced from a molten alloy produced by melting the raw material metals, it is preferable to obtain a solidified product (alloy ingot) through a casting process of pouring, into a mold, the molten alloy produced by melting the raw material metals, and molding the molten alloy.

### Ingot Pulverization

The alloy ingots obtained in the casting process are then pulverized, whereby an alloy powder having a desired particle size and a desired particle size distribution can be prepared. Examples of the pulverization method include a dry method and a wet method using an organic solvent such as ethylene glycol, hexane, or acetone.

### Classification of Alloy Powder

The alloy powder pulverized in the pulverization process is adjusted to the desired mass median diameter D50 and particle size distribution using a sieving device with a mesh such as a vibrating screen or a sifter, an inertial classification device such as an air separator, or a centrifuge such as a cyclone.

The particle size of the alloy powder must be adjusted depending on the activity of the metal elements configuring the alloy powder, and the mass median diameter D50 is usually 100 m or less, and preferably 80 μm or less, and is usually 0.1 μm or greater, and preferably 0.5 m or greater.

### Production of Phosphor

A nitriding reaction is carried out using the alloy powder. In the nitriding treatment of the alloy powder, first, a crucible or a tray is filled with the alloy powder. Examples of the material of the crucible or tray used here include boron nitride, silicon nitride, aluminum nitride, molybdenum, and tungsten.

The crucible or tray filled with the alloy powder is then placed in a heating furnace for which the atmosphere can be controlled, after which a nitrogen-containing gas is circulated therein to thoroughly purge the inside of the system with the nitrogen-containing gas. If necessary, the inside of the system may be evacuated to a vacuum state, after which the nitrogen-containing gas may be circulated. The nitrogen-containing gas used in the nitriding treatment is a gas containing nitrogen, and examples thereof include nitrogen, ammonia, and a mixed gas of nitrogen and hydrogen.

The nitriding treatment is carried out by heating in a state of being filled with the nitrogen-containing gas or in a state in which the nitrogen-containing gas is circulated. The pressure is not particularly limited as long as a phosphor according to one embodiment of the present invention is obtained, but in the embodiments exemplified below, the pressure is preferably set to be equal to or higher than the atmospheric pressure for the purpose of preventing the mixing in of oxygen from the atmosphere.

When the pressure of the nitrogen-containing gas in the nitriding treatment is set to be equal to or higher than the atmospheric pressure, a deterioration in the characteristics of the obtained phosphor due to the mixing in of a large amount of oxygen in a case in which the sealing property of the heating furnace is poor can be prevented. In one embodiment, the pressure of the nitrogen-containing gas is, in terms of the gauge pressure, usually 50 MPa or higher, preferably 100 MPa or higher, more preferably 120 MPa or higher, and even more preferably 150 MPa or higher, and is usually 300 MPa or lower, and preferably 250 MPa or lower. In a specific embodiment, the pressure is 150 MPa or greater and 250 MPa or less.

Furthermore, since an increase in pressure occurs in association with an increase in temperature, the target pressure can be obtained at the maximum temperature by adjusting the system to a lower temperature and pressure in accordance with the maximum temperature and maximum pressure and then increasing the temperature.

In an embodiment in which the temperature and pressure are adjusted at the initial stage of the nitriding treatment, in terms of MPa per hour, the rate of pressure increase after the initial temperature and pressure adjustments have been completed is usually on average 5.0 MPa/hr or greater and 30 MPa/hr or less, and is preferably 10 MPa/hr or greater, and preferably 20 MPa/hr or less.

In one embodiment of the embodiment A, by setting the rate of pressure increase to the above lower limit or greater, firing can be completed within an appropriate time, and by setting the rate of pressure increase to the above upper limit or less, a preferable phosphor containing stacking faults or having stacking faults localized therein as described above can be obtained.

Moreover, in one embodiment of the embodiment B, by setting the rate of pressure increase to the above lower limit or greater, firing can be completed within an appropriate time, and by setting the rate of pressure increase to the above upper limit or less, a preferable phosphor containing the crystal phase B or having the crystal phase B localized therein as described above as described above can be obtained.

The reason for this is that by slowing the rate of pressure increase, it takes a relatively long time to reach the stage in which crystal growth mainly occurs, from the stage in which crystal nucleation mainly occurs. During this time, relaxation of self-stress of the dislocations advances, localization of the dislocations (also referred to as dislocation recovery or dislocation polygonization) is promoted, and in the embodiment A, dislocation expansion (that is, the formation of the stacking faults) is promoted, and thereby a phosphor containing stacking faults in an appropriate form is obtained, while in the embodiment B, dislocation expansion (that is, the formation of the stacking faults and the crystal phase B) is promoted, and thereby a phosphor containing the crystal phase B in an appropriate form is obtained.

The maximum temperature in the nitriding treatment is usually 800 °C or higher, preferably 1200 °C or higher, and more preferably 1500 °C or higher, and is usually 2200 °C or lower, preferably 2100 °C or lower, and more preferably 2000 °C or lower. The time required for the nitriding treatment can be prevented from becoming long by setting the maximum temperature to 800 °C or higher. On the other hand, by setting the maximum temperature to 2200 °C or lower, volatilization or decomposition of the nitride to be produced is prevented, and a phosphor having a desired composition is easily obtained.

The heating time (the holding time at the maximum temperature) during the nitriding treatment may be the time necessary for the reaction between the alloy powder and the nitrogen, and is usually 1 minute or longer, preferably 10 minutes or longer, more preferably 30 minutes or longer, and even more preferably 60 minutes or longer. When the heating time is 1 minute or longer, the nitriding reaction proceeds sufficiently, and a phosphor having a high level of characteristics is easily obtained. From the viewpoint of production efficiency, the upper limit of the heating time is usually 24 hours or less, preferably 20 hours or less, more preferably 15 hours or less, and even more preferably 12 hours or less. In a specific embodiment in which the maximum temperature is 1500 °C or higher, the heating time is preferably 8 hours or less, more preferably 5 hours or less, and even more preferably 3 hours or less.

After the nitriding treatment of the alloy, the obtained phosphor is preferably subjected to pulverization and a classification treatment. For example, the obtained phosphor can be subjected to pulverization and classification such that 90% or more of the obtained phosphor particles have a particle size of preferably 5 μm or greater and 30 μm or less, more preferably 7 μm or greater and 27 μm or less, even more preferably 10 μm or greater and 25 μm or less, and particularly preferably 12 μm or greater and 20 μm or less. After the nitriding treatment, a post-treatment process such as washing and drying may be included. By pulverizing and classifying the phosphor into particles of the above range, optical properties such as light absorption efficiency are improved, and phosphor particles having excellent optical characteristics can be obtained.

### Nitride Method

When the phosphor according to the first embodiment is to be produced by a nitride method, the phosphor is produced by mixing the respective phosphor raw materials and firing the obtained phosphor raw material mixture. In particular, in order to obtain the phosphor according to the first embodiment, conditions may be appropriately set based on the technical production concept of dividing the process into a step of generating crystal nuclei and a step of growing crystals. These methods may be used individually, or multiple methods may be combined and used.

The production method of the present invention is described more specifically below, but a phosphor according to the first embodiment can be obtained by making appropriate adjustments based on the above.

Examples of the phosphor raw materials include metal compounds and metals. For example, in the case of producing a phosphor having a composition of a crystal phase represented by the above formula [1], the phosphor can be produced by mixing a necessary combination of a raw material of the element Sr (hereinafter, appropriately referred to as the “Sr source”), a raw material of the element Ca (hereinafter, appropriately referred to as the “Ca source”), a raw material of the element Al (hereinafter, appropriately referred to as “Al source”), a raw material of the element Si (hereinafter, appropriately referred to as the “Si source”), a raw material of the element N (hereinafter, appropriately referred to as the “N source”), and a raw material of an M element (hereinafter, appropriately referred to as the “M source”) (mixing step), firing the obtained mixture (firing step), and optionally crushing, pulverizing, and/or washing the obtained fired product (post-treatment step).

### Phosphor Raw Material

As the phosphor raw materials to be used, any known raw materials may be used. Among the M sources, specific examples of the Eu source include Eu₂O₃, Eu₂(SO₄)₃, Eu₂(C₂O₄)₃·10H₂O, EuF₂, EuF₃, EuCl₂, EuCl₃, Eu(NO₃)₃₋₆H₂O, EuN, and EuNH. Among these, a nitride, an oxide, or a halide is preferable, and EuN is more preferable. A higher purity of the Eu source to be used is preferable, and the purity thereof is usually 98% or higher, and preferably 99% or higher.

Specific examples of raw materials for other activating elements such as Mn, Ce, Pr, Nd, Sm, Tb, Dy, Ho, Er, Tm, and Yb include compounds obtained by replacing Eu with the Mn, Ce, Pr, Nd, Sm, Tb, Dy, Ho, Er, Tm, and Yb, respectively, in the compounds given as specific examples of the Eu source.

Specific examples of the Sr source include SrO, Sr(OH)₂·8H₂O, SrCO₃, Sr(NO₃)₂, SrSO₄, Sr(C₂O₄)·H₂O, Sr(OCOCH₃)₂·0.5H₂O, SrF₂, SrCl₂, Sr₃N₂, Sr₃N₄, and SrNH. Among these, SrO, SrCO₃, Sr₂N, and Sr₃N₂ are preferable, and Sr₂N and Sr₃N₂ are more preferable.

Specific examples of the Ca source include CaO, Ca(OH)₂, CaCO₃, Ca(NO₃)₂·4H₂O, CaSO₄·2H₂O, Ca(C₂O₄)·H₂O, Ca(OCOCH₃)₂·H₂O, CaF₂, CaCl₂), Ca₂N, Ca₃N₂, and CaNH. Among these, CaO, CaCO₃, Ca₂N, and Ca₃N₂ are preferable.

As a specific example of the Al source, AlN is preferably used. As a specific example of the Si source, SiO₂ or Si₃N₄ is preferably used. A compound that becomes SiO₂ during the reaction may also be used. Specific examples of such compounds include SiO₂, H₄SiO₄, and Si(OCOCH₃)₄.

### Mixing Step

The phosphor raw materials are weighed so as to obtain the target composition, and are sufficiently mixed using a ball mill or the like to obtain a phosphor raw material mixture (mixing step). The mixing method is not particularly limited, and a known method can be used.

### Firing Step

Subsequently, the phosphor raw material mixture obtained in the mixing step is fired (firing step). The above-described phosphor raw material mixture is dried as necessary, and then a container such as a crucible is filled with the raw material mixture, and the mixture is fired using a heating furnace, a pressurized furnace, or the like. The firing temperature varies depending on other conditions such as pressure, but the maximum temperature is usually 800 °C or higher, preferably 1200 °C or higher, and more preferably 1500 °C or higher, and is usually 2200 °C or lower, preferably 2100 °C or lower, and more preferably 2000 °C or lower. The time required for the nitriding treatment can be prevented from becoming long by setting the maximum temperature to 800 °C or higher. On the other hand, by setting the maximum temperature to 2200 °C or less, volatilization or decomposition of the nitride to be produced is prevented, and a phosphor having a desired composition is easily obtained. The rate of temperature increase is usually 2 °C/min or greater, and preferably 5 °C/min or greater, and is usually 30 °C/min or less, and preferably 25 °C/min or less.

The pressure and the rate of pressure increase during firing can be the same as those in the alloy method.

The firing atmosphere may be any firing atmosphere as long as a phosphor according to the first embodiment can be obtained, but is preferably a nitrogen-containing atmosphere. In addition, an atmosphere containing an alkaline earth metal element, for example, strontium is also preferable for obtaining a phosphor according to the first embodiment. The firing time (the holding time at the maximum temperature) varies depending on the temperature, pressure, or the like during firing, but is usually 1 minute or longer, preferably 10 minutes or longer, more preferably 30 minutes or longer, and even more preferably 60 minutes or longer. When the heating time is 1 minute or longer, the nitriding reaction proceeds sufficiently, and a phosphor having a high level of characteristics is easily obtained. From the viewpoint of production efficiency, the upper limit of the heating time is usually 24 hours or less, preferably 20 hours or less, more preferably 15 hours or less, and even more preferably 12 hours or less. In a specific embodiment in which the maximum temperature is 1500 °C or higher, the heating time is preferably 8 hours or less, more preferably 5 hours or less, and even more preferably 3 hours or less.

### Post-Treatment Step

The fired product obtained as described above may be subjected to a post-treatment step such as a classification step, a washing step, or a drying step.

### Phosphor-Containing Composition

With regard to the embodiments A and B, the phosphor according to the first embodiment can be used by being mixed with a liquid medium. In particular, when the phosphor according to the first embodiment is to be used in applications such as a light-emitting device, the phosphor is preferably used in a form of being dispersed in a liquid medium. A composition obtained by dispersing the phosphor according to the first embodiment in a liquid medium may be referred to as a “phosphor-containing composition according to the first embodiment”.

### Phosphor

The type of the phosphor according to the first embodiment and contained in the phosphor-containing composition according to the first embodiment is not limited, and can be optionally selected from those described above. Moreover, as the phosphor according to the first embodiment and contained in the phosphor-containing composition according to the first embodiment, a single type may be used alone or any combination of two or more types may be used at any ratio. Furthermore, the phosphor-containing composition according to the first embodiment may contain a phosphor other than the phosphor according to the first embodiment as long as the effects of the present invention are not significantly impaired.

### Liquid Medium

The liquid medium used in the phosphor-containing composition according to the first embodiment is not particularly limited as long as the performance of the phosphor is not impaired within the desired range. For example, any inorganic material and/or organic material can be used as long as the material exhibits liquid properties under the desired usage conditions, allows the phosphor according to the first embodiment to be suitably dispersed therein, and does not cause an undesirable reaction, and examples thereof include silicone resin, epoxy resin, and polyimide silicone resin.

### Liquid Medium and Phosphor Content

The content of the phosphor and liquid medium in the phosphor-containing composition according to the first embodiment may be optionally set as long as the effects of the present invention are not significantly impaired. For example, with respect to the entire phosphor-containing composition according to the first embodiment, the content of the liquid medium is usually 50 mass % or more and preferably 75 mass % or more, and is usually 99 mass % or less and preferably 95 mass % or less.

### Other Components

The phosphor-containing composition according to the first embodiment may contain other components in addition to the phosphor and the liquid medium as long as the effects of the present invention are not significantly impaired. Furthermore, a single type of other component may be used alone, or two or more types thereof may be used in any combination and ratio.

### Light-Emitting Device

With regard to embodiments A and B, one embodiment of the present invention is a light-emitting device provided with a first light emitter and a second light emitter that emits visible light upon irradiation with light from the first light emitter, wherein the second light emitter includes the phosphor according to the first embodiment.

The description of the phosphor described above can be applied as is to each of the configurations and characteristics of the phosphor according to the first embodiment, the phosphor thereof being included in the light-emitting device of the present embodiment.

Here, as the second light emitter, a single type of phosphor may be used alone, or two or more types of phosphors may be used in any combination and ratio. Moreover, the second light emitter may also contain a phosphor in addition to the phosphor according to the first embodiment.

In one embodiment, the light-emitting device is a light-emitting device in which the second light emitter includes at least a red phosphor, further includes a green phosphor and/or a yellow phosphor, and includes the phosphor according to the first embodiment as the red phosphor or the yellow phosphor.

Moreover, in a specific embodiment, the green phosphor and/or the yellow phosphor includes one or more selected from the group consisting of a garnet-based phosphor, a silicate-based phosphor, a nitride phosphor, and an oxynitride phosphor.

Specifically, when configuring a light-emitting device, the yellow phosphor preferably has an emission peak wavelength in a wavelength range of 550 nm or greater and 600 nm or less, and the green phosphor preferably has an emission peak wavelength in a wavelength range of 500 nm or greater and 560 nm or less. Moreover, an orange or red phosphor is one having an emission peak wavelength in a wavelength range of usually 615 nm or greater, preferably 620 nm or greater, more preferably 625 nm or greater, and even more preferably 630 nm or greater, and of usually 660 nm or less, preferably 650 nm or less, more preferably 645 nm or less, and even more preferably 640 nm or less.

By appropriately combining phosphors in the above wavelength ranges, a light-emitting device exhibiting excellent color reproducibility can be provided. The excitation light source may have a peak emission wavelength in a wavelength range of less than 420 nm.

Hereinafter, some specific embodiments of the light-emitting device for cases in which the phosphor according to the first embodiment is used as a yellow phosphor or a red phosphor will be described, but the present embodiment is not limited thereto.

In the above cases, the light-emitting device of the present embodiment can be, for example, in the following form (X), (Y), or (Z).
(X): An aspect in which the second light emitter includes at least one or more yellow phosphors and one or more red phosphors, and the yellow phosphor or the red phosphor includes at least the phosphor according to the first embodiment.
(Y): An aspect in which the second light emitter includes at least one or more green phosphors and one or more red phosphors, and the red phosphor includes at least the phosphor according to the first embodiment.
(Z): An aspect in which the second light emitter includes at least one or more yellow phosphors, one or more green phosphors, and one or more red phosphors, and the yellow phosphor or the red phosphor includes at least the phosphor according to the first embodiment.

In the above embodiment, a commercially available product can be used as the green phosphor and/or the yellow phosphor other than the phosphor according to the first embodiment, and for example, a garnet-based phosphor, a silicate-based phosphor, a nitride phosphor, or an oxynitride phosphor can be used. In a specific embodiment, the yellow phosphor and/or the green phosphor includes one or more selected from the group consisting of a garnet-based phosphor, a silicate-based phosphor, a nitride phosphor, and an oxynitride phosphor.

### Yellow Phosphor

Examples of the garnet-based phosphor that can be used as the yellow phosphor other than the phosphor according to the first embodiment include (Y, Gd, Lu, Tb, La)₃(Al, Ga)₅O₁₂:(Ce, Eu, Nd); examples of the silicate-based phosphor include (Ba, Sr, Ca, Mg)₂SiO₄:(Eu, Ce); and examples of the nitride phosphor and the oxynitride phosphor include (Ba, Ca, Mg)Si₂O₂N₂:Eu (SION based phosphor), (Li, Ca)₂(Si,Al)₁₂(O,N)₁₆:(Ce, Eu) (α-sialon phosphor), (Ca, Sr)AlSi₄(O,N)₇:(Ce, Eu) (1147 phosphor), and (La, Ca, Y, Gd)₃(Al,Si)₆N₁₁:(Ce, Eu) (LSN phosphor).

One of these may be used alone, or two or more thereof may be used in combination.

Among these, as the yellow phosphor, a garnet-based phosphor is preferable, and among the garnet-based phosphors, a YAG-based phosphor represented by Y₃Al₄O₁₂:Ce is most preferable.

### Green Phosphor

Examples of garnet-based phosphors that can be used for the green phosphor include (Y, Gd, Lu, Tb, La)₃(Al,Ga)₅O₁₂:(Ce, Eu, Nd), Ca₃(Sc, Mg)₂Si₃O₁₂:(Ce, Eu) (CSMS phosphor); examples of silicate-based phosphors include (Ba, Sr, Ca, Mg)₃SiO₁₀:(Eu, Ce), (Ba, Sr, Ca, Mg)₂SiO₄:(Ce, Eu) (BSS phosphor); examples of the oxide phosphor include (Ca, Sr, Ba, Mg)(Sc, Zn)₂O₄:(Ce, Eu) (CASO phosphor); examples of the nitride phosphor and oxynitride phosphor include (Ba, Sr, Ca, Mg)Si₂O₂N₂:(Eu, Ce), Si_{6-z}Al_{z}O_{z}N_{8-z}:(Eu, Ce) (β-sialon phosphor) (0<z≤1), (Ba, Sr, Ca, Mg, La)₃(Si,Al)₆O₁₂N₂:(Eu, Ce) (BSON phosphor), and (La, Ca, Y, Gd)₃(Al, Si)₆N₁₁:(Ce, Eu) (LSN phosphor).

One of these may be used alone, or two or more thereof may be used in combination.

### Red Phosphor

Examples of phosphors that can be used as the red phosphor other than the phosphor according to the first embodiment include other orange or red phosphors such as a garnet-based phosphor, a sulfide phosphor, a nanoparticle or quantum dot phosphor, a nitride phosphor, and an oxynitride phosphor.

As other orange or red phosphors, for example, the following phosphors can be used.

Examples of the sulfide phosphor include (Sr, Ca)S:Eu (CAS phosphor) and La2O2S:Eu (LOS phosphor); examples of the garnet-based phosphor include (Y, Lu, Gd, Tb)₃Mg₂AlSi₂O₁₂:Ce; examples of the nanoparticles or quantum dots include phosphors composed of combinations of Group II-VI, Group III-V, and Group IV-VI metals, such as CdSe; and examples of nitride or oxynitride phosphors include (Sr, Ca)AlSiN₃:Eu (S/CASN phosphor), (CaAlSiN₃)₁₋ₓ·(SiO₂N₂)x:Eu (CASON phosphor), (La, Ca)₃(Al, Si)₆N₁₁:Eu (LSN phosphor), (Ca, Sr, Ba)₂Si₅(N, O)₈:Eu (258 phosphor), (Sr, Ca)Al₁₊ₓSi₄₋ₓOₓN₇₋ₓ:Eu (1147 phosphor), Mx(Si, Al)₁₂(O,N)₁₆:Eu (where M is Ca, Sr, or the like) (α-sialon phosphor), and Li(Sr, Ba)Al₃N₄:Eu (all of the above x's satisfying 0<x<1).

One of these may be used alone, or two or more thereof may be used in combination.

### Light-Emitting Device Configuration

The light-emitting device according to the present embodiment has a first light emitter (excitation light source), and can use at least the phosphor according to the first embodiment as a second light emitter, but the configuration thereof is not limited, and any known device configuration can be adopted.

As the first light emitter, an LED element having a light-emitting structure formed of various semiconductors such as a GaN-based semiconductor, a ZnO-based semiconductor, and a SiC-based semiconductor can be used.

Examples of the device configuration and the embodiment of the light-emitting device include those described in JP 2007-291352 A.

In addition, the LED element may be fixed to a package such as a bullet-shaped package or an SMD type package, or may be directly fixed onto a circuit board as in the case of a chip-on-board type light-emitting device. The form of optical coupling between the LED element and the phosphor is not limited, and the space between the two may be simply filled with a transparent medium (including air), or an optical element such as a lens, an optical fiber, a light guide plate, or a reflection mirror may be interposed between the two.

A structure in which phosphor particles are dispersed in a translucent matrix is typically formed by curing a resin paste in which the particulate phosphor is dispersed. In addition to a structure in which an LED element is embedded in the cured product of such a paste, various structures can be adopted, such as a structure in which the cured product covers a portion of the surface of the LED element in a film shape, and a structure in which a film formed of the cured product is disposed at a position separated from the LED element.

### Light-Emitting Device Applications

With regard to the embodiments A and B, applications of the light-emitting device according to the present embodiment are not particularly limited, and the light-emitting device can be used in various fields in which ordinary light-emitting devices are used, but the light-emitting device according to the present embodiment has a wide color reproduction range and an advanced color rendering property and thus is particularly preferably used as a light source of a lighting device or an image display device.

### Lighting Device

One embodiment of the present invention is a lighting device provided with the light-emitting device as a light source.

When the light-emitting device is applied in a lighting device, the specific configuration of the lighting device is not limited, and the light-emitting device as described above may be appropriately incorporated into a known lighting device. Examples include a surface-emitting lighting device in which a large number of light-emitting devices are arranged on the bottom surface of a holding case.

### Image Display Device

One embodiment of the present invention is an image display device provided with the light-emitting device as a light source.

When the light-emitting device is used as a light source for an image display device, the specific configuration of the image display device is not limited, but the light-emitting device is preferably used together with a color filter. For example, when the image display device is a color image display device that uses a color liquid crystal display element, the image display device can be formed by using the light-emitting device as a backlight, and combining the light-emitting device with an optical shutter that uses a liquid crystal, and with a color filter having red, green, and blue pixels.

### Vehicle Indicator Lamp

One embodiment of the present invention is a vehicle indicator lamp that is provided with the light-emitting device as a light source.

In a specific embodiment, the light-emitting device used in the vehicle indicator lamp is preferably a light-emitting device that emits white light. In the light-emitting device that emits white light, the light emitted from the light-emitting device preferably has a deviation duv (also referred to as Δuv) of light color from a black body locus of from −0.0200 to 0.0200 and a color temperature of 5000 K or higher and 30000 K or lower.

In another specific embodiment, the light-emitting device used in the vehicle indicator lamp is preferably a light-emitting device that emits red light. In this embodiment, for example, the light-emitting device may serve as a vehicle indicator lamp of red light by absorbing blue light emitted from a blue LED chip and emitting red light.

Vehicle indicator lamps include vehicle headlamps, side lamps, tail lamps, turn signals, brake lamps, fog lamps, and other lightings provided in a vehicle for the purpose of providing some kind of indication to other vehicles, people, or the like.

### EXAMPLES

The present invention will be described more specifically with reference to examples below, but the present invention is not limited to the following examples as long as a departure from the essence of the present invention does not occur.

### Measurement Method

### Chromaticity Measurement

The emission spectrum was measured at room temperature (25 °C) using a 150 W xenon lamp as an excitation source and the FP-6500 spectrofluorometer (available from JASCO Corporation) equipped with the C7041 multi-channel CCD detector (available from Hamamatsu Photonics K.K.) as a spectrum measurement apparatus.

From data of a wavelength range from 480 nm to 780 nm of the emission spectrum obtained by the above-described method, the x and y chromaticity coordinates in the colorimetric system (CIE 1931 colorimetric system) were calculated as the x and y chromaticity coordinates in the XYZ colorimetric system specified by JIS Z8701 (1999) using a method conforming to JIS Z8724 (1997).

### Internal Quantum Efficiency Measurement

A sample was prepared in which a phosphor powder was uniformly sealed in a transparent resin at a constant mass fraction, and the sample was irradiated with an excitation light having a wavelength of 455 nm in the LMS-200 integrating sphere (available from Labsphere, Inc.), and the converted light spectral radiant flux was measured using the Solid Lambda spectroscope (available from Spectra Co-op). The internal quantum efficiency was calculated from the measured converted light spectral radiant flux and the spectral radiant flux of the excitation light measured in advance. Note that the phosphor powder used in this measurement was a powder (average particle size: from 10 to 30 m) of the phosphor produced in Example 1 or Comparative Example 1 described below.

Observation with Transmission Electron Microscope

Since the space group of the crystal structure of the oxynitride phosphor could not be narrowed down by an XRD measurement alone (see R. J. HILL, J. Appl. Cryst. (1992). 25, 589 to 610, etc.), the space group was confirmed by a method (see Journal of Ceramics Society of Japan, 117 (1), 94-98 (2009), etc.) of analyzing a convergent beam electron diffraction (CBED) pattern from the phosphor particles produced in Example 1 or Comparative Example 1 described below using a transmission electron microscope (hereinafter, which may be referred to as a TEM). Furthermore, in recent years, it has become possible to directly observe atomic arrangements by a method of analyzing an image obtained using an atomic resolution aberration corrected bright field scanning transmission electron microscope (STEM), and in light thereof, the space group confirmed by TEM-CBED was re-examined using an annular bright-field (ABF) STEM method and an integrated differential phase contrast (iDPC) STEM method, and the distribution of stacking faults or the distribution of the crystal phase B was further clarified.

In order to obtain a TEM-CBED pattern from the phosphor particles, or in order to obtain an ABF-STEM image and an iDPC-STEM image, phosphor particle processing suitable for observation using a TEM is required. The processing thereof required four steps: (1) embedding the phosphor particles in a resin or supporting them on a thin needle; (2) processing the cross section; (3) confirming the crystal orientation of individual particles exposed on the cross section; and (4) obtaining a thin film plate piece having an approximate thickness of from 100 nm to 10 nm and having a plane parallel to the (100) plane when the sample is assumed to have a CASN crystal structure. Several methods are available for step (1), such as a method of embedding a plurality of particles in an epoxy resin, and a method of bonding one particle to the tip of a tungsten needle having a thickness of 1 μm using an epoxy resin, and the present inventors used both of these methods. The steps (2) to (4) will be described along with the devices that were used therein.

(2) The SM-09010 (trade name: Cross-Section Polisher) available from JEOL Ltd. was used to carry out argon ion processing at an acceleration voltage of 5.00 kV.

(3) The crystal orientation of the particle cross section was confirmed using the JSM-7000F field emission type scanning electron microscope (FE-SEM), available from JEOL Ltd., equipped with an OIM crystal orientation analyzer (Electron Back Scattering Diffraction: EBSD) available from TSL Solutions. At this time, the acceleration voltage of the electronic beam was adjusted to 20 kV.

(4) From the information obtained in (3), a search was conducted for particles close to the (100) plane in the case in which the sample was assumed to have a CASN crystal structure, and a thin film plate piece having an approximate thickness of from 100 nm to 10 nm and having a plane parallel to the (100) plane was obtained by a focused ion beam method (FIB).

The detailed conditions for the FIB method that was used were as follows:
Sample surface treatment: A carbon film was formed using a high vacuum vapor deposition device, after which a tungsten film was formed using a FIB device.

### (1) Method for Preparing Test Piece for TEM-CBED Observation

A microsampling method was used.
Fabrication device: FB-2000A focused ion beam processing device available from Hitachi, Ltd.
Acceleration voltage: 30 kV, FIB normal processing
Acceleration voltage: 10 kV, FIB thinning processing

### (2) Method for Preparing Test Piece for ABF-STEM Observation

The microsampling method was used.
Fabrication device: NB5000 Hitachi focused ion/electronic beam processing and observation device available from Hitachi High-Tech Fielding Corporation (now: Hitachi High-Tech Corporation)
Acceleration voltage: 40 kV, FIB trench processing
Acceleration voltage: 30 kV, FIB chunk rough processing
Acceleration voltage: 20 kV, FIB chunk precision processing
Acceleration voltage: 10 kV, FIB thinning processing and carbon deposition protective film formation
Acceleration voltage: 5 kV, FIB finish processing
   (3) Method for Preparing Test Piece for iDPC-STEM Observation
A dry pulverization and dry dispersion method was used.

The following devices were used to collect TEM-CBED patterns from the samples.
Device: TECNAI G2 F20 field emission transmission electron microscope available from FEI Company
Acceleration voltage: 200 kV
Observation direction: [100](assuming the same crystal structure as CASN)
Image recording: CCD camera
Measurement temperature: room temperature

The following devices were used to collect ABF-STEM images from the sample.
Device: GrandARM atomic resolution aberration-corrected transmission scanning electron microscope available from JEOL Ltd.
Acceleration voltage: 80 kV
Observation direction: [100](assuming the same crystal structure as CASN)
Image recording: ABF detector
Measurement temperature: room temperature

The following devices were used to collect iDPC-STEM images from the sample.
Device: Spectra 300 available from Thermo Fisher Scientific, Inc.
Acceleration voltage: 300 kV
Observation direction: [100](assuming the same crystal structure as CASN)
Image recording: Panther STEM detection system
Measurement temperature: room temperature

### Phosphor Preparation

### Example 1

Each metal was weighed so that the metal element composition ratio was Al:Si=1:1 (molar ratio), and the raw material metals were melted in a high-frequency induction melting furnace in an argon atmosphere using a graphite crucible, and then poured from the crucible into a mold and solidified to obtain an alloy (master alloy) having a metal element composition ratio of Al:Si=1:1 (molar ratio).

The master alloy and other raw material metals were weighed so that the metal element composition ratio was Eu:Sr:Ca:Al:Si=0.0068:0.95:0.043:1:1 (molar ratio). The inside of the furnace was evacuated to 5×10⁻² Pa, after which the evacuation was stopped, and the inside of the furnace was filled with argon to a predetermined pressure. The master alloy in a calcia crucible was melted in the furnace, after which Sr, Eu, and Ca were added thereto, the molten metal in which all the components were melted was stirred by an induced current and confirmed, after which the molten metal was poured from the crucible into a water-cooled copper mold (having a plate shape with a thickness 40 mm) and solidified.

The obtained alloy exhibited an X-ray diffraction pattern similar to that of Sr(Si_{0.5}Al_{0.5})₂, and the alloy was identified as an intermetallic compound called an AlB2-type alkaline earth silicide. This plate-shaped alloy ingot was pulverized in a nitrogen stream to obtain an alloy powder, and 160 g of the alloy powder was mixed with 1.36 g of Eu₂O₃ to obtain a mixed powder. A tray made of boron was then filled with the mixed powder and set in a hot isostatic pressing device (HIP device).

The inside of the device was then evacuated to 20 Pa and then heated to 300 °C, and the evacuation was continued at 300 °C for 1 hour. Subsequently, the initial temperature and pressure were adjusted so that the nitrogen pressure at 600 °C inside the system was 100 MPa, after which the pressure was increased to 196 MPa at an average rate of pressure increase of 8.6 MPa/hr. In parallel with the pressure increase, the temperature in the system was increased such that the temperature was 1950 °C when the pressure increase was completed, and the pressure and temperature were maintained at 196 MPa and 1950 °C for 2 hours. The temperature and pressure inside of the system were reduced to normal temperature and normal pressure, after which the material was pulverized, washed, and dried, and a phosphor (SCASN phosphor) of Example 1 was obtained.

### Comparative Example 1

A CASN phosphor (product number: BR-101/L) available from Mitsubishi Chemical Corporation was prepared.

### Phosphor Evaluation

For each phosphor, a selected area diffraction pattern in the [100] direction was observed using a TEM. The results of Example 1 are presented in FIGS. 2A and 2B, and the results of Comparative Example 1 are presented in FIG. 2C. A slight diffraction indicative of the (001) plane was confirmed in Example 1, whereas no corresponding diffraction was observed in Comparative Example 1.

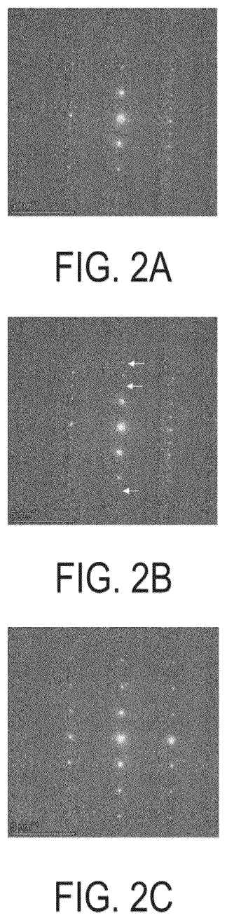

Further, each phosphor was observed from the [100] direction using a TEM to obtain a bright-field image. The results of Example 1 and Comparative Example 1 are presented in FIGS. 3A and 3B, respectively. In Comparative Example 1, no stacking faults were present, or no sub-phase corresponding to the crystal phase B was present, and relatively many dislocations and grain boundaries were observed. On the other hand, a linear dark area was observed in Example 1, that is, it is clear that stacking faults parallel to the (002) plane extended in the <010> direction were generated. From the above, it is considered that the residual stress is extremely reduced in Example 1 as compared with Comparative Example 1. It should be noted that the maximum value of the spacing between the stacking faults in Example 1 was 2 μm, and the density of the stacking faults in the normal direction was 5×10³ cm⁻¹.

A selected area diffraction pattern and a TEM-CBED pattern were collected for a stacking fault-free region of the phosphor according to Example 1.

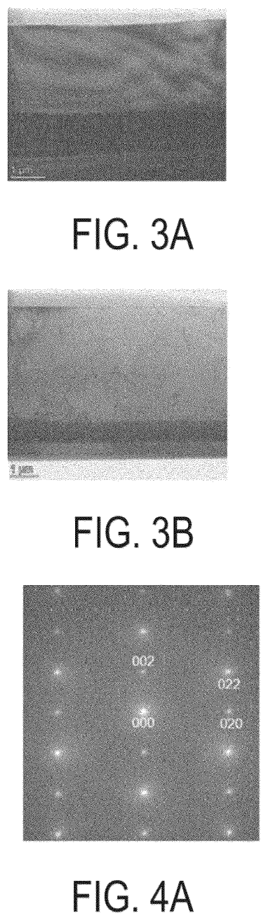

FIG. 4A is a selected area diffractogram in a circular region with a diameter of 500 nm, and FIG. 4B is a centrally enlarged pattern of the CBED pattern. The diffraction disks of the intensity distribution appearing in this CBED pattern were examined for symmetry within a single disk or between disks to determine the point group, and the space groups Cmc2₁ and Pbcn were identified. In FIG. 4A, there is no 001 diffraction reflection specific to Pbcn, and in FIG. 4B, a mirror surface showing the symmetry of the orthorhombic crystal structure is observed under conditions parallel to the <002> and <100> directions. In addition, a dark line suggesting the presence of a two-fold helical axis parallel to the c-axis direction is observed in the 002 diffraction disc in FIG. 4B. The TEM-CBED measurements and analysis results of the above example offer a conclusion that the crystal structure has a point group of mm2 and a space group of Cmc2₁, rather than the space group candidates P2₁ and Pbcn suggested by XRD alone.

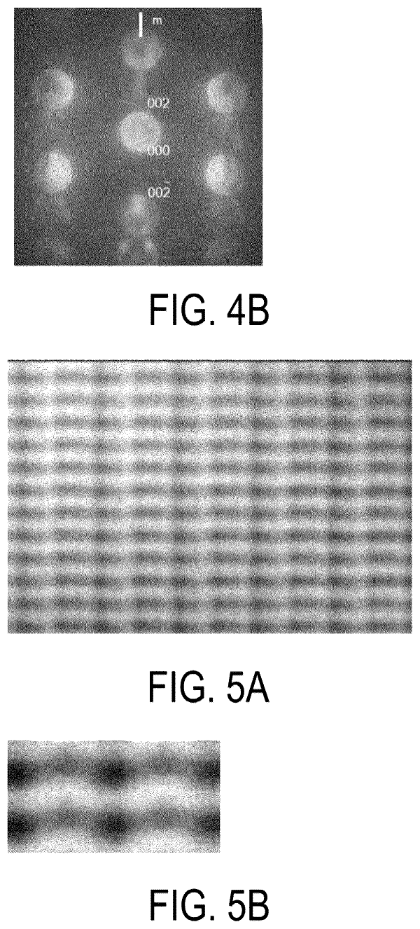

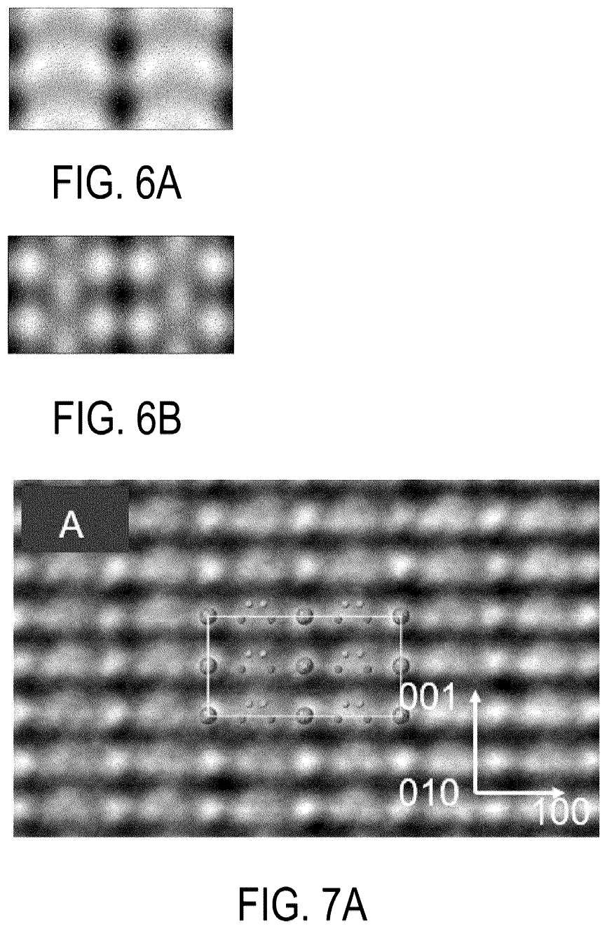

In addition, an ABF-STEM image was collected for a stacking fault-free region of the phosphor according to Example 1. The results and an enlarged image are presented in FIG. 5A and FIG. 5B. In addition, for a phosphor having the same composition as in Example 1, an image obtained by simulating a STEM bright-field image that should appear in calculations for the phosphor having a space group of Cmc2₁ is presented in FIG. 6A. Similarly, FIG. 6B is a simulated STEM bright-field image of a phosphor having the same composition as in Example 1 and having a space group of Pbcn. FIGS. 6A and 6B are images that were calculated under conditions including a de-focus Δf=4 nm and a thickness t=19.6 nm.

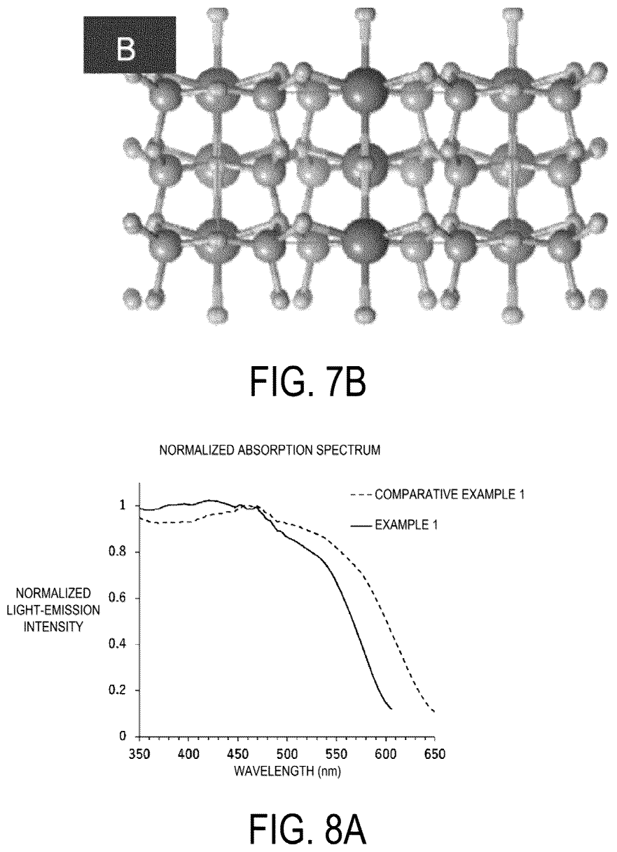

In addition, iDPC-STEM images were also collected for a stacking fault-free region of the phosphor according to Example 1. The results are shown in FIG. 7A. FIG. 7B is an atomic model.

As is clear from a comparison between the FIGS. 5A and 5B, FIGS. 6A and 6B, and FIGS. 7A and 7B, in the region not containing stacking faults, the phosphor according to Example 1 did not match Pbcn, but exhibited very good matching with the Cmc2₁ perfect crystal.

Thus, the results of TEM-CBED, ABF-STEM and iDPC-STEM offer a conclusion that the crystal structure in the region where no stacking fault exists is Cmc2₁. Note that in Example 1, the stacking fault-free region was present for approximately 5 μm in the <002> direction.

In Example 1, the region where stacking faults were present was observed only at the edge of the TEM test piece. The structural features thereof include having a (001) diffraction reflection that cannot occur with Cmc2₁ and linearly advancing in the <002> direction, suggesting a stacking fault in which the (002) occupied by the nitrogen atom row is displaced in the ¼<020> direction from the Cmc2₁ position.

In other words, in Example 1, the crystal phase B was observed only at the edge of the TEM test piece. The structural features thereof include having a (001) diffraction reflection that cannot occur with Cmc2₁ and linearly advancing in the <002> direction, suggesting a stacking fault in which the (002) occupied by the nitrogen atom row is displaced in the ¼<020> direction from the Cmc2₁ position. In this case, the structure of the region in which the stacking fault exists corresponds to the structure in which the sheet B is inserted, as illustrated in FIGS. 1B and 1D, and the region thereof exhibits a localized Pbcn structure.

It is quite possible that the origin of the stacking faults is due to the dislocations, which are accumulated by molecular plane growth, expanding in association with being transferred to the prism surface (change in the crystal growth surface). The regions in which the stacking faults exist were localized in Example 1, and from this fact, it can be said that in the method for producing the phosphor of Example 1, relaxation of the self-stress of the dislocations advanced at the growth stage of the molecular plane, and the dislocations were localized (also referred to as dislocation recovery or dislocation polygonization). In other words, the structure of the phosphor of Example 1 indicates that polygonization of dislocations having an effect of relaxing stress and an expansion into stacking faults occurred.

From the above, it is understood that the phosphor of Example 1 includes a region (crystal phase A) composed of the Cmc2₁ as a main phase. In addition, the region (crystal phase B) where stacking faults occurred due to the expansion of dislocations can be regarded as a localized Pbcn structure, and the diffraction showing the (001) plane that was slightly confirmed in Example 1 is considered to be derived from the localized Pbcn structure.

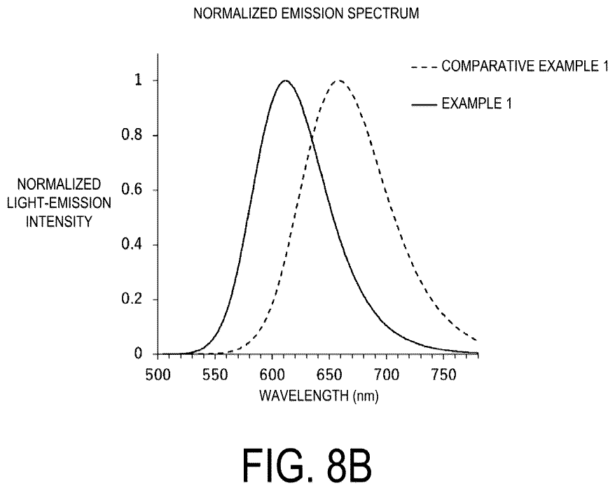

The normalized absorption spectrum and the normalized emission spectrum of each phosphor are presented in FIGS. 8A and 8B, respectively, and the emission peak wavelengths and the peak full width at half maximum are shown in Table 1. As shown in Table 1, it is clear that the phosphor of Example 1 has a narrower peak full width at half maximum and exhibits better luminescence characteristics than the phosphor of Comparative Example 1.

TABLE 1

| | Emission Peak | Peak Full Width at |
|---|---|---|
| | Wavelength (nm) | Half Maximum (nm) |
| Comparative Example 1 | 658 | 87 |
| Example 1 | 612 | 75 |

As indicated above, it is understood that both the CASN phosphor of Comparative Example 1 and the SCASN phosphor of Example 1 are phosphors having Cmc2₁ as the main phase. It is well known that in a case in which no stacking fault is present, in general, a crystal structure having the same space group as the main phase has the same environment around the Eu²⁺ ion serving as the central element of the phosphor, and the peak full width at half maximum is also substantially equivalent.

In addition, the phosphor of Example 1 has few dislocations and contains stacking faults, and therefore it is considered that the residual stress is reduced as compared with the phosphor of Comparative Example 1.

Furthermore, the phosphor according to the present embodiment is considered to exhibit excellent luminescence characteristics perhaps due to the stacking faults being localized as a result of polygonization of the dislocations before expansion, and the presence of a region of low strain that is considered to be an almost perfect crystal.

Although various embodiments are described above with reference to the drawings, the present invention is of course not limited to such embodiments. It will be apparent to those skilled in the art that various changes and modifications can be made within the scope of the claims, and it should be understood that such changes and modifications naturally fall within the technical scope of the present invention. In addition, the constituent elements in the above-described embodiments may be arbitrarily combined without departing from the gist of the invention.

The present application is based on patent applications (JP 2023-206225 A and JP 2023-206226 A) filed in Japan on Dec. 6, 2023, the contents of which are incorporated herein by reference.

### INDUSTRIAL APPLICABILITY

The light-emitting device according to the present embodiment has a wide color reproduction range and a high color rendering property, and thus can be particularly preferably used as a light source of a lighting device or image display device.

1. A phosphor comprising a crystal phase having a composition represented by Formula [1],
the phosphor including stacking faults, and
in a direction perpendicular to the stacking faults, a maximum value of a spacing between the stacking faults being 50 nm or greater:
ReₓMA₁₋ₓMB_{b}MC_{c}D_{d} [1]
where
Re includes one or more elements selected from the group consisting of Eu, Mn, Ce, Pr, Nd, Sm, Tb, Dy, Ho, Er, Tm, and Yb,
MA includes one or more elements selected from the group consisting of Ca, Sr, Ba, and Mg,
MB includes one or more elements selected from the group consisting of Al, B (boron), Ga, In, and Sc,
MC includes one or more elements selected from the group consisting of Si, Ge, Ti, and Hf,
D includes one or more elements selected from the group consisting of N (nitrogen), O (oxygen), F (fluorine), Cl, Br, and I (iodine), and also at least N (nitrogen), and
x, b, c, and d each independently satisfy the following:
0.0<x≤0.2
0.7≤b≤1.3
0.7≤c≤1.3
2.4≤d≤3.6.

2. The phosphor according to claim 1, wherein, in the direction perpendicular to the stacking faults, the maximum value of the spacing between the stacking faults is 100 nm or greater.

3. The phosphor according to claim 1, wherein a density of the stacking faults in a normal direction is 2×10⁵ cm⁻¹ or greater.

4. The phosphor according to claim 1, wherein a space group of the crystal phase having a composition represented by Formula [1] is any of Cmc2₁, Pbcn, P1, P-1, and a space group belonging to a maximal non-isomorphic subgroup derived from Cmc2₁ and Pbcn.

5. A phosphor comprising a crystal phase A and a crystal phase B,
both the crystal phase A and the crystal phase B including a composition represented by Formula [1], and
the crystal phase A and the crystal phase B having mutually different space groups:
ReₓMA₁₋ₓMB_{b}MC_{c}D_{d} [1]
where
Re includes one or more elements selected from the group consisting of Eu, Mn, Ce, Pr, Nd, Sm, Tb, Dy, Ho, Er, Tm, and Yb,
MA includes one or more elements selected from the group consisting of Ca, Sr, Ba, and Mg,
MB includes one or more elements selected from the group consisting of Al, B (boron), Ga, In, and Sc,
MC includes one or more elements selected from the group consisting of Si, Ge, Ti, and Hf,
D includes one or more elements selected from the group consisting of N (nitrogen), O (oxygen), F (fluorine), Cl, Br, and I (iodine), and also at least N (nitrogen), and
x, b, c, and d each independently satisfy the following:
0.0<x≤0.2
0.7≤b≤1.3
0.7≤c≤1.3
2.4≤d≤3.6.

6. The phosphor according to claim 5, wherein a volume occupancy rate of the crystal phase A is 60% or greater and less than 100% when a total of volume occupancy rates of the crystal phase A and the crystal phase B is 100%.

7. The phosphor according to claim 5, wherein the space groups of the crystal phase A and the crystal phase B having the composition represented by Formula [1] are each any one of Cmc2₁, Pbcn, P1, P-1, and a space group belonging to a maximal non-isomorphic subgroup derived from Cmc2₁ and Pbcn.

8. A light-emitting device comprising a first light emitter and a second light emitter that emits visible light when irradiated with light from the first light emitter,
the second light emitter including the phosphor described in claim 1.

9. A light-emitting device comprising a first light emitter and a second light emitter that emits visible light when irradiated with light from the first light emitter,
the second light emitter including the phosphor described in claim 1,
wherein the second light emitter includes at least a red phosphor, further includes a green phosphor and/or a yellow phosphor, and includes, as the red phosphor or the yellow phosphor, the phosphor described in claim 1.

10. The light-emitting device according to claim 9, wherein the green phosphor and/or the yellow phosphor includes one or more selected from the group consisting of a garnet-based phosphor, a silicate-based phosphor, a nitride phosphor, and an oxynitride phosphor.

11. A lighting device comprising, as a light source, the light-emitting device described in claim 8.

12. An image display device comprising, as a light source, the light-emitting device described in claim 8.

13. A vehicle indicator lamp comprising, as a light source, the light-emitting device described in claim 8.

14. A light-emitting device comprising a first light emitter and a second light emitter that emits visible light when irradiated with light from the first light emitter,
the second light emitter including the phosphor described in claim 5.

15. A light-emitting device comprising a first light emitter and a second light emitter that emits visible light when irradiated with light from the first light emitter,
the second light emitter including the phosphor described in claim 5,
wherein the second light emitter includes at least a red phosphor, further includes a green phosphor and/or a yellow phosphor, and includes, as the red phosphor or the yellow phosphor, the phosphor described in claim 5.

16. The light-emitting device according to claim 15, wherein the green phosphor and/or the yellow phosphor includes one or more selected from the group consisting of a garnet-based phosphor, a silicate-based phosphor, a nitride phosphor, and an oxynitride phosphor.

17. A lighting device comprising, as a light source, the light-emitting device described in claim 14.

18. An image display device comprising, as a light source, the light-emitting device described in claim 14.

19. A vehicle indicator lamp comprising, as a light source, the light-emitting device described in claim 14.
